(19) United States
(12) Patent Application Publication
(10) Pub. No.: US 2008/0237562 A1
(43) Pub. Date: Oct. 2, 2008

(54) PHASE CHANGE MEMORY DEVICES AND FABRICATION METHODS THEREOF

(75) Inventors: Yi-Chan Chen, Yunlin County (TW); Chih-Wei Chen, Miaoli County (TW); Hong-Hui Hsu, Changhua County (TW); Chien-Min Lee, Kaohsiung City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/955,293

(22) Filed: Dec. 12, 2007

(30) Foreign Application Priority Data
Mar. 30, 2007 (TW) TW96111267

(51) Int. Cl. H01L 45/00

(52) U.S. Cl. 257/3; 438/102; 257/E45.002

(57) ABSTRACT

Phase change memory devices and fabrication methods thereof. A phase change memory device comprises a stacked heating element with a conductive portion and a relatively high resistive portion, wherein the relatively high resistive portion includes a nitrogen-containing metal silicide part. The heating stacked element such as a highly resistive nitrogen-containing metal silicide (MSiₓN_{y}) is formed by a self-aligned silicidizing and nitrifying process. Self-aligned silicidization can be achieved by nitrogen ion implantation or nitrogen-containing plasma treatment. The resistance of the heating element can be regulated by adjusting the content of nitrogen or degree of nitrification.

### BACKGROUND OF THE INVENTION

1. Field of the Invention

The invention relates to memory devices and fabrication methods for the memory devices, and in particular to phase change memory devices and fabrication methods thereof.

2. Description of the Related Art

Phase change memory devices are non-volatile, highly readable, highly programmable, and low driving voltage/current devices, and popularly applied in non-volatile memory devices. A current technological developmental trend for phase change memory devices is to increase cell density and reduce programming current.

Conventional phase change materials in a phase change memory device have at least two solid phases, a crystalline state and an amorphous state. Transformation between these two phases can be achieved by heating the phase change materials. Different electrical pulses can be selectively input to the phase change materials. The phase change materials can exhibit different electrical characteristics depending on their state. For example, a crystalline phase change material with periodic atomic arrangement can exhibit low electrical resistance, while an amorphous phase change material with irregular atomic arrangement can exhibit high electrical resistance. The difference in electrical resistances between the crystalline state and the amorphous state can be as high as four orders. Such phase change materials may transform between numerous electrically detectable conditions of varying resistance within a nanosecond time scale with the input of a pico joules of energy. Among various phase change materials, alloys containing Ge, Sb, and Te are widely applied to modern phase change memory devices.

Since phase transformation between different states of the phase change material is reversible, memory status can be distinguished by telling whether a memory bit is in a low resistance state (crystalline state) or in a high resistance state (amorphous state). More specifically, by deciding among different resistances of a crystalline state or an amorphous state, a digital memory status “0” or “1” can be read or write on a phase change memory cell.

In order to reduce operation current of a phase change memory device, high resistive electrode material is introduced to improve heating efficiency. Meanwhile, reset current density for inducing phase transformation for the phase change memory device can be also reduced. A document published in J. Appl. Phys. Vol. 94 (2003) p. 3536, the entirety of which is hereby incorporated by reference discloses a phase change memory device. By disposing a high resistive heating layer between a phase change material and a conductive layer, heating efficiency can be improved and current for driving phase transformation can be thus reduced.

FIG. 1 is a cross section of a conventional phase change memory (PCM) device. Referring to FIG. 1, a silicon substrate 10 includes word lines (WL) and switching devices such as an MOS transistor for controlling a phase change memory cell. A dielectric layer is disposed on the silicon substrate 10. A through hole is formed in the lower portion of the dielectric layer 20. A conductive material 30 such as tungsten (W) is filled in the through hole. A trench is formed at the upper portion of the dielectric layer 20. A conductive layer is filled in the trench to serve as a bit line (BL) 50 of the PCM device. A phase change layer 40 is disposed on the BL 50 and a buffer layer 45 such as TiN is interposed therebetween. Conventional PCM devices use a high resistive material 35 as a heating layer interposed between the phase change layer 40 and the conductive layer 30. The high resistive material 35 can provide excellent heating efficiency and can reduce reset current for driving phase transformation. Forming the conductive layer 30 and the phase change layer 40 composed of different materials using conventional semiconductor fabrication techniques, however, can be intricate and tedious.

U.S. Pat. No. 6,946,673, the entirety of which is hereby incorporated by reference discloses a method of locally increasing resistance between the phase change material and the conductive material to improve heating efficiency and reduce reset current for driving phase transformation. FIG. 2 is a cross section of another conventional phase change memory (PCM) device. Referring to FIG. 2, a dielectric layer 60 is disposed on a silicon substrate 55. A through hole is formed in the dielectric layer 60 and is filled with a conductive material 65 such as W. A phase change layer 80 is disposed on the dielectric layer 60 and electrically connects to the conductive layer 65. Another conductive 90 is formed on the phase change layer 80 to serve as bit line (BL) of the PCM device. The upper portion 70 (serving as a heating electrode) of the conductive layer 65 is nitrified by doping nitrogen such that resistance of the heating electrode is increased as the doped nitrogen concentration increases. An applied voltage exceeding threshold voltage (Vₜₕ) is biased on the heating electrode 70, thereby directly heating the phase change material and transforming at least one portion 85 thereof.

The resistance change of the conductive material 65 due to nitrification is dependent on vertical distribution of the nitrogen doping concentration. Meanwhile, it is beneficial that overall voltage drop is avoided on the heating electrode during operation. However, since the resistance of the heating electrode depends on vertical distribution of the nitrogen doping concentration, it eludes those skilled in the art to consistently fabricate desired nitrogen doping distribution.

### BRIEF SUMMARY OF THE INVENTION

A detailed description is given in the following embodiments with reference to the accompanying drawings.

Embodiments of the PCM devices are related at a heating element with locally high resistance to reduce read/write current for the PCM device and to improve integrity of the PCM device. Furthermore, with the help of a self-aligned silicidizing and nitrifying processes, the fabrication process window can be efficiently improved.

An embodiment of the invention provides a phase change memory device, comprising: a heating element with a conductive portion and a relatively high resistive portion; and a phase change memory layer stacked with the heating element; wherein the relatively high resistive portion comprises a nitrogen-containing metal silicide part.

Another embodiment of the invention further provides a method for fabricating a phase change memory device, comprising: providing a semiconductor substrate with a first dielectric layer disposed on the semiconductor layer, wherein the first dielectric layer comprises a through hole therein; forming a heating element in the through hole, wherein the heating element comprises a conductive portion and a relatively high resistive portion; and forming a phase change memory layer on the first dielectric layer stacked with the heating element, wherein the relatively high resistive portion comprises a nitrogen-containing metal silicide part.

### BRIEF DESCRIPTION OF THE DRAWINGS

The invention can be more fully understood by reading the subsequent detailed description and examples with references made to the accompanying drawings, wherein:

FIG. 1 is a cross section of a conventional phase change memory (PCM) device;

FIG. 2 is a cross section of another conventional phase change memory (PCM) device;

FIGS. 3-8B are cross sections of each fabrication step for a PCM device with a locally high resistance heating element according to an exemplary embodiment of the invention; and

FIGS. 9-13 are cross sections of each fabrication step for a PCM device with a locally high resistance heating element according to another exemplary embodiment of the invention.

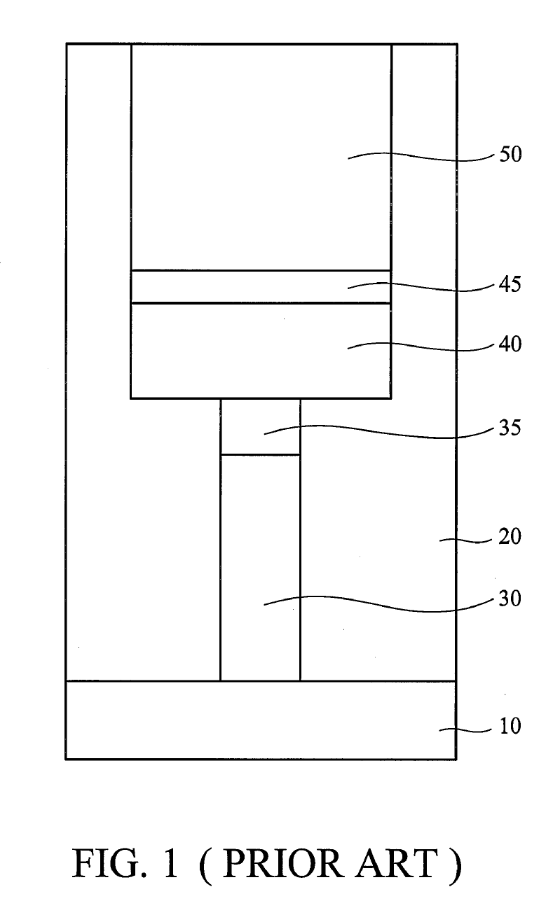

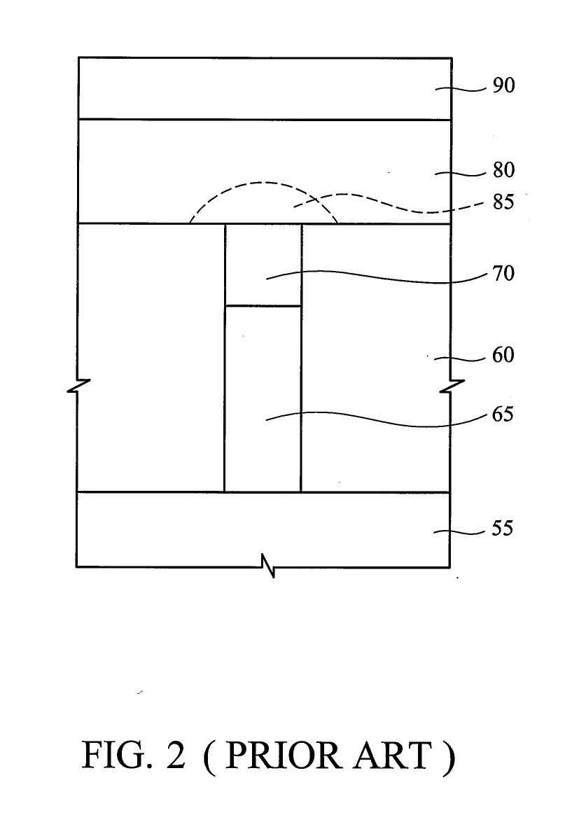

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Embodiments of the invention provide a heating element with locally high resistance to reduce write current for the PCM device. The heating element such as a highly resistive nitrogen-containing metal silicide (MSiₓN_{y}) is formed by a self-aligned silicidizing and nitrifying process. Self-aligned silicidization can be achieved by nitrogen ion implantation or nitrogen-containing plasma treatment. The resistance of the heating element can be regulated by adjusting the content of nitrogen or degree of nitrification.

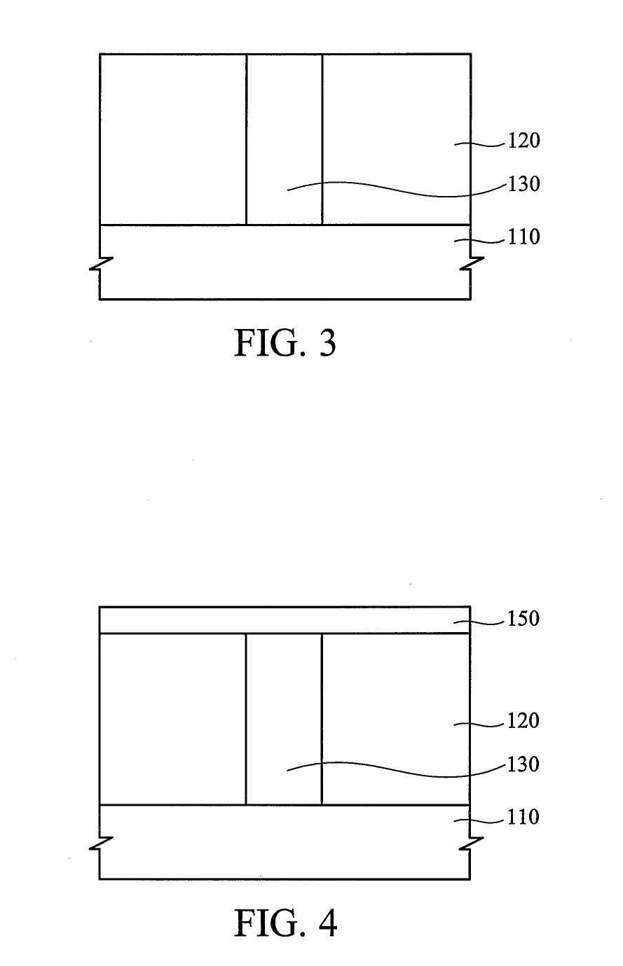

FIGS. 3-8B are cross sections of each fabrication step for a PCM device with a locally high resistance heating element according to an exemplary embodiment of the invention. Referring to FIG. 3, a substrate 110 such as a silicon substrate includes word lines (WL) and switching devices such as a MOS transistor for controlling a phase change memory cell. A first dielectric layer 120 is disposed on the substrate 110. A through hole is formed in the lower portion of the first dielectric layer 120. A first metal layer 130 is filled in the through hole. The first metal layer 130 can comprises Ti, W, Ta, Co, Mo, Ni, Pt, TiAl, TiW, or single/multiple combinations thereof.

As a main feature and a key aspect of the invention, formation of the heating element in the through hole comprises filling a first metal layer in the through hole, wherein in the first metal layer is level with the first dielectric layer. Subsequently, a silicon layer is formed on the first dielectric layer such that a portion of the silicon layer directly contacts the first metal layer. A step of heat treatment is performed to form a metal silicide layer on an interface between the silicon layer and the first metal layer. The metal silicide layer is nitrified and transformed into a nitrogen-containing metal silicide layer.

Referring to FIG. 4, a silicon layer 150 is formed on the first dielectric layer 120 such that a portion of the silicon layer 150 directly contacts the first metal layer 130. The silicon layer 150 can comprise a polysilicon layer or an amorphous silicon layer formed by chemical vapor deposition (CVD) or sputtering. According to an embodiment of the invention, an isolated layer (not shown) is formed by any well-known patterning technique between the silicon layer 150 and the first metal layer 130 such that the silicon layer 150 directly contacts the first metal layer 130 only at the specified region.

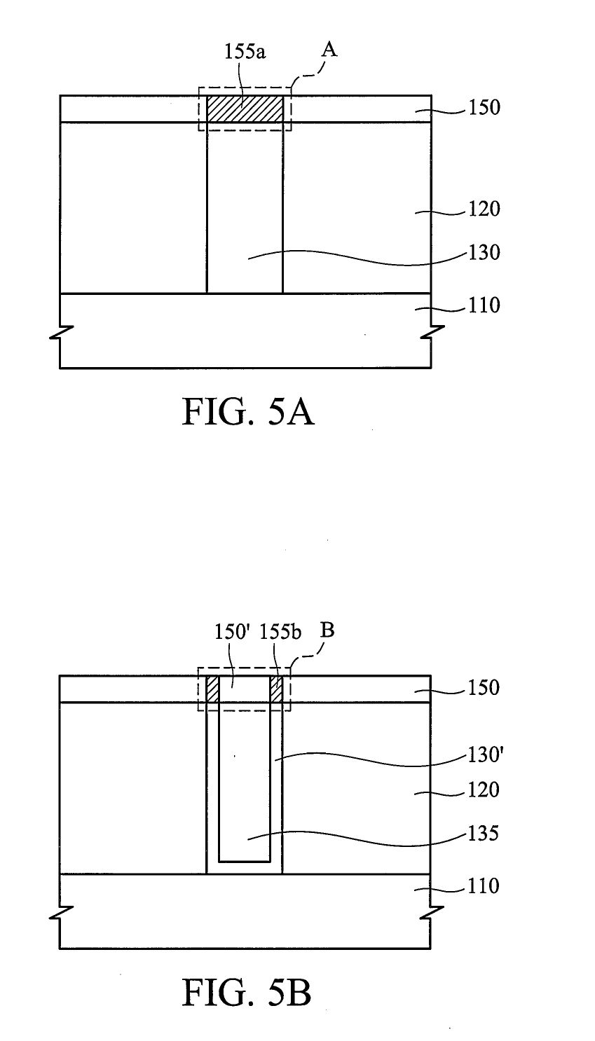

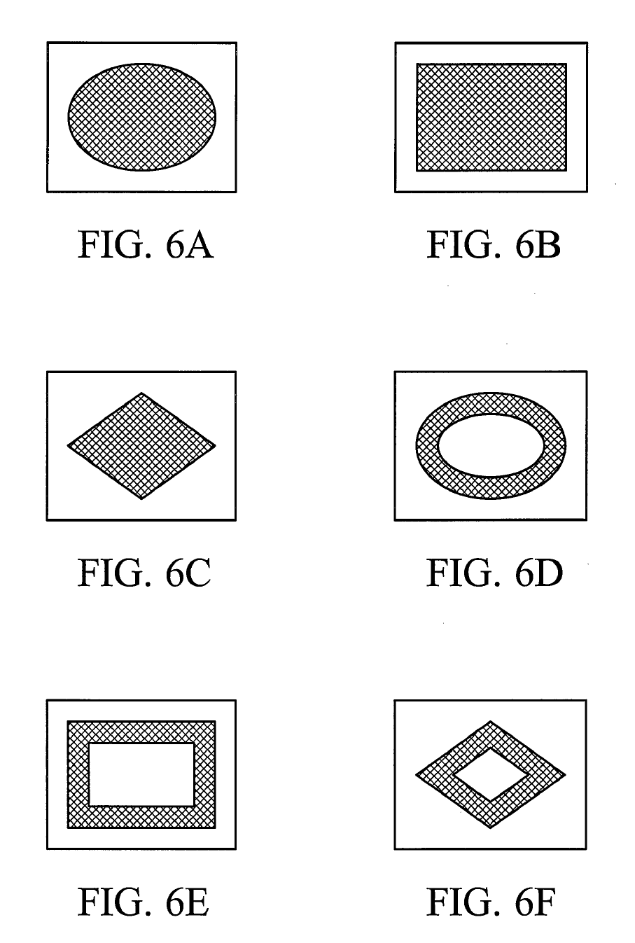

Referring to FIG. 5A, a step of heat treatment is performed to form a metal silicide 155a at the contact area between the silicon layer 150 and the first metal layer 130. The temperature range for the procedure of heat treatment is approximately 600° C.-800° C. Since the resistance of the metal silicide 155a is higher than that of the first metal layer 130, the metal silicide 155a is suitable to serve as the heating element of the PCM cell. The size and shape of the metal silicide 155a is the same as that of the first metal layer 130 such as a solid circle, a solid oval, a solid square, a solid rectangle, or a solid rhombus. Top views of the metal silicide 155a at location A are shown in FIGS. 6A-6C.

Referring to FIG. 5B, according to another embodiment of the invention, the silicon layer 150 directly contacts the first metal layer 130′ only at the specific region. More specifically, the first metal layer 130′ is lined in the through hole, and an insulation layer 135 (e.g., silicon oxide or silicon nitride) is subsequently filled in the through hole. Consequently, the metal silicide 155b is formed only at the specific region, while the other region of the silicon layer is un-reacted 150′. The heating area of the PCM cell is more concentrated, i.e., more heating efficiency is presented. The shape of the metal silicide 155b can be a hollow circle, a hollow oval, a hollow square, a hollow rectangle, or a hollow rhombus. Top views of the metal silicide 155b at location B are shown in FIGS. 6D-6F.

According to another embodiment of the invention, after silcidization of the heating element, the un-reacted silicon layer 150 is optionally removed before nitrification. The following description, however, depicts the un-reacted silicon layer 150 as remaining on the first dielectric layer.

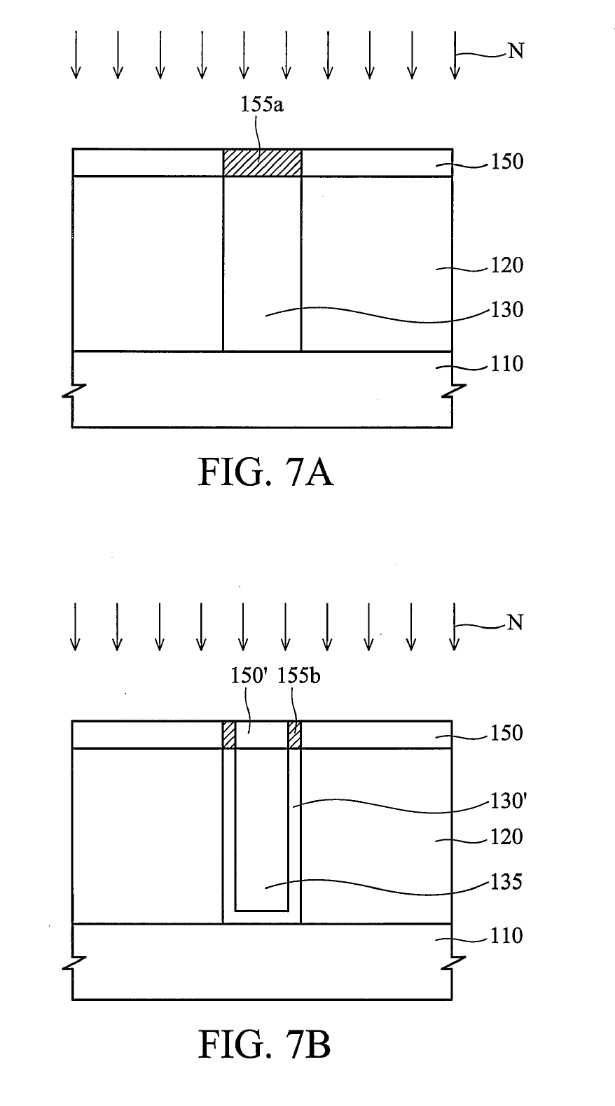

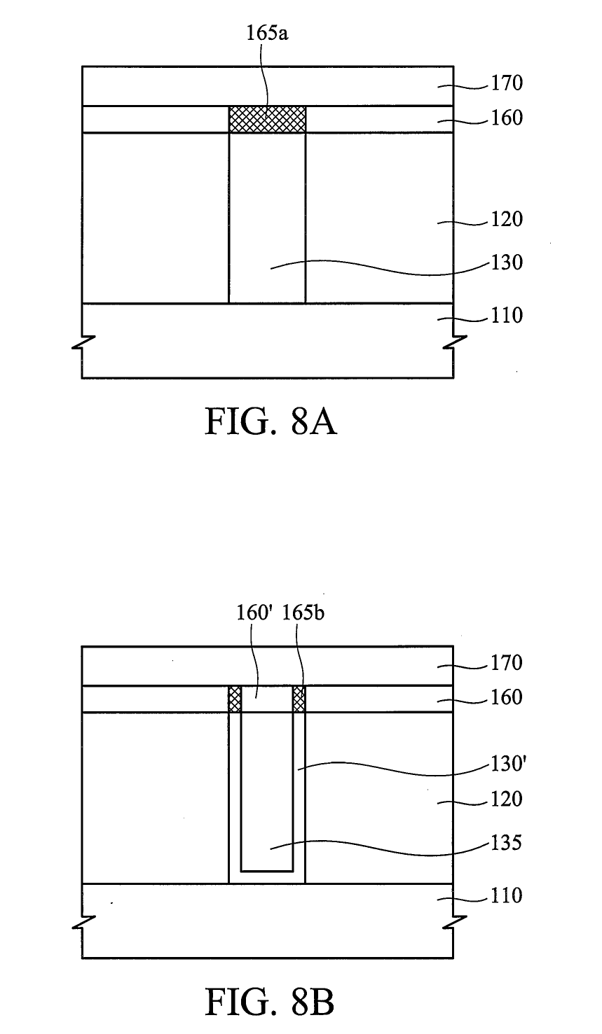

Referring to FIG. 7A, a step of nitrification N is performed transforming the metal silicide layer 155a into nitrogen containing metal silicide 165a (as shown in FIG. 8A). The un-reacted silicon layer 150 is also nitrified forming silicon nitride 160 (as shown in FIG. 8A). Exemplary nitrification N comprises nitrogen ion implantation or nitrogen containing plasma treatment. The nitrogen containing metal silicide 165a is depicted as MSiₓN_{y}, where M is the first metal preferably comprising Ti, W, Ta, Co, Mo, Ni, Pt, TiAl, TiW, or single/multiple combinations thereof, and where x and y are respectively comprise silicon and nitrogen. For example, x is approximately in a range of 1.5-2.3, and y is approximately in a range of 1-3.

Referring to FIG. 7B, according to another embodiment of the invention, the metal silicide 155b at the specific area is nitrified into a nitrogen containing metal silicide 165b (as shown in FIG. 8B). The un-reacted silicon regions 150 and 150′ are also nitrified forming silicon nitride regions 160 and 160′ (as shown in FIG. 8B).

Referring to FIG. 8A and FIG. 8B, a PCM layer 170 is formed on the first dielectric layer 120 and stacked with the heating element. More specifically, the PCM layer 170 is exemplarily disposed on the silicon nitride 160 and the nitrogen containing metal silicide 165a as shown in FIG. 8A. The PCM layer 170 is made of an alloy or compound comprising Ge, Sb, and Te. There are additional steps not mentioned here, which are required to complete the PCM device such as digital line (DL) formation and metallization, but which are not essential to the understanding of the invention, as such will therefore not be described.

According to embodiments described, the highly resistive nitrogen containing metal silicide (MSiₓN_{y}) can effectively provide joule heating during operation, reducing driving current and threshold voltage for the PCM device. Since the nitrogen containing metal silicide (MSiₓN_{y}) can be formed on a contact plug or as a predetermined ring shape, heating on the PCM layer can be further concentrated.

As another main feature and key aspect, formation of the heating element can alternatively comprise forming a second metal layer on the first dielectric layer electrically connecting to the first metal layer. A second dielectric layer is formed on the first dielectric layer, wherein the second dielectric layer is patterned to form an opening exposing the second metal layer at a specific region. A silicon layer is formed on the second dielectric layer such that the silicon layer directly contacts the second metal layer at the specific region. A step of heat treatment is performed to form a metal silicide layer on an interface between the silicon layer and the first metal layer. The metal silicide layer is nitrified and transformed into the nitrogen-containing metal silicide layer.

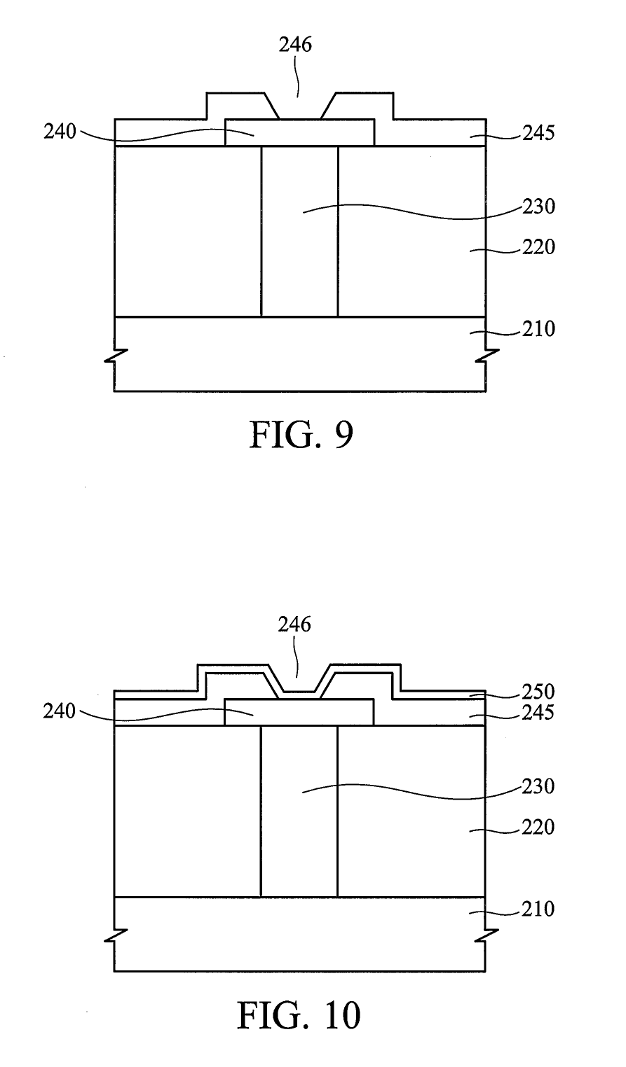

FIGS. 9-13 are cross sections of each fabrication step for a PCM device with a locally high resistant heating element according to another exemplary embodiment of the invention. Referring to FIG. 9, a substrate 210 such as a silicon substrate includes word lines (WL) and switching devices such as a MOS transistor for controlling a phase change memory cell. A first dielectric layer 220 is disposed on the substrate 210. A through hole is formed in the lower portion of the first dielectric layer 220. A first metal layer 230 such as W is filled in the through hole. A patterned second metal layer 240 is formed on the first dielectric layer 220 and contacts the first metal layer 230. The second metal layer 240 can comprise Ti, W, Ta, Co, Mo, Ni, Pt, TiAl, TiW, or single/multiple combinations thereof. Subsequently, a second dielectric layer 245 is conformably formed on the first dielectric layer 220 and the patterned second metal layer 240. An opening 246 is formed in the second dielectric layer 245 exposing a predetermined region of the second metal layer 240. The opening 246 can be of any shape and size such as a solid circle, a solid oval, a solid square, a solid rectangle, a solid rhombus, a hollow circle, a hollow oval, a hollow square, a hollow rectangle, or a hollow rhombus. Furthermore, the shape and size of the opening 246 are independent from those of the patterned second metal layer 240.

Referring to FIG. 10, a silicon layer 250 is conformably formed on the second dielectric layer 245 and directly contacts the exposed second metal layer 240. The silicon layer 250 can comprise a polysilicon layer or an amorphous silicon layer formed by chemical vapor deposition (CVD) or sputtering.

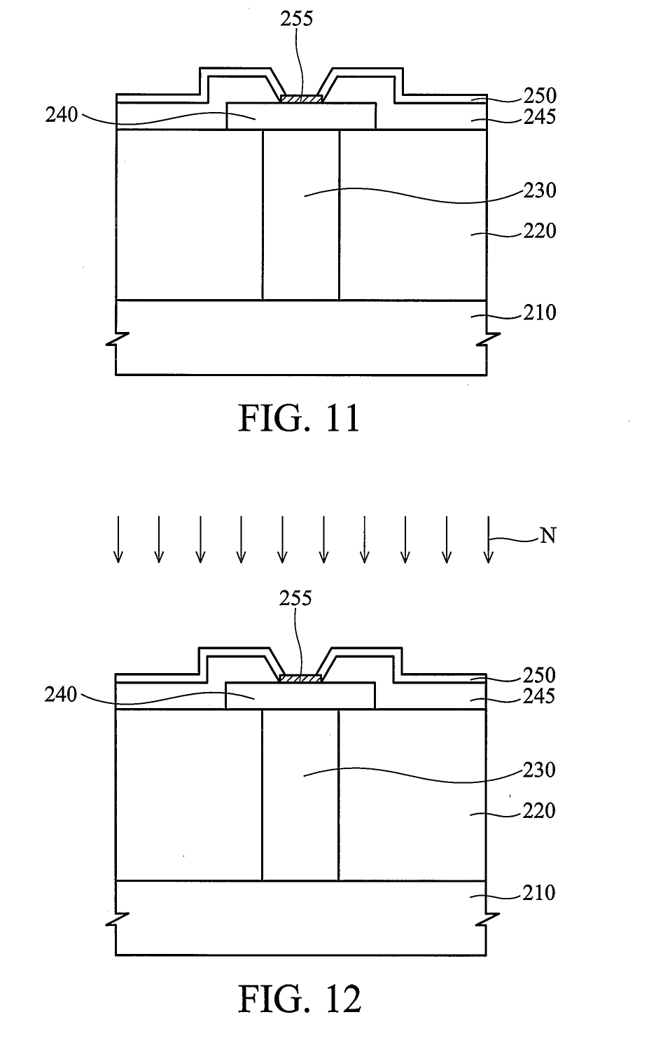

Referring to FIG. 11, a step of heat treatment is performed to form a metal silicide 255 at the contact area between the silicon layer 250 and the second metal layer 240. The temperature range for the procedure of heat treatment is approximately 600° C.-800° C. Since the resistance of the metal silicide 255 is higher than that of the second metal layer 240, the metal silicide 255 is suitable to serve as the heating element of the PCM cell. The size and shape of the metal silicide 255 is the same as that of the exposed second metal layer 240.

According to another embodiment of the invention, after silidization of the heating element, the un-reacted silicon layer 250 is optionally removed before nitrification. The following description, however, depicts the un-reacted silicon layer 250 as remaining on the first dielectric layer.

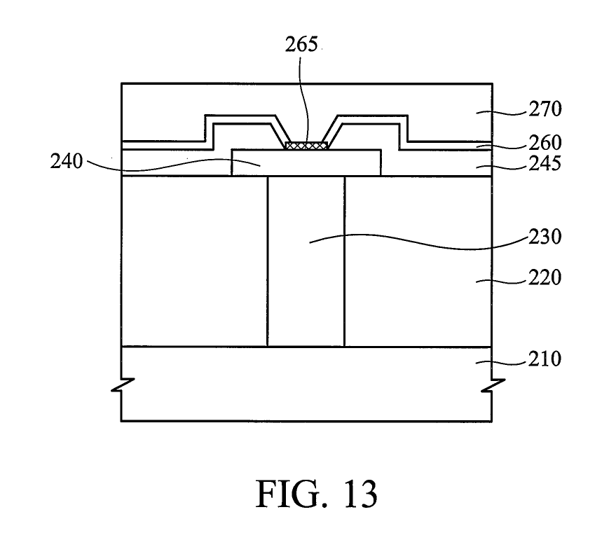

Referring to FIG. 12, a step of nitrification N is performed transforming the metal silicide layer 255 into nitrogen containing metal silicide 265 (as shown in FIG. 13). The un-reacted silicon layer 150 is also nitrified forming silicon nitride 260 (as shown in FIG. 13). An exemplary step of nitrification N comprises nitrogen ion implantation or nitrogen containing plasma treatment. The nitrogen containing metal silicide 265 is depicted as MSiₓN_{y}, where M is the first metal preferably comprising Ti, W, Ta, Co, Mo, Ni, Pt, TiAl, TiW, or single/multiple combinations thereof, and where x and y are respectively silicon and nitrogen. For example, x is approximately in a range of 1.5-2.3, and y is approximately in a range of 1-3.

Referring to FIG. 13, a PCM layer 270 is formed on the second dielectric layer 245 and stacked with the heating element. More specifically, the PCM layer 270 is exemplarily disposed on the silicon nitride 260 and the nitrogen containing metal silicide The PCM layer 270 is made of an alloy or compound comprising Ge, Sb, and Te. There are additional steps not mentioned here, which are required to complete the PCM device such as digital line (DL) formation and metallization, but which are not essential to the understanding of the invention, as such will therefore not be described.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a heating element with a conductive portion and a relatively high resistive portion; and
a phase change memory layer stacked with the heating element;
wherein the relatively high resistive portion comprises a nitrogen-containing metal silicide part.

2. The phase change memory device as claimed in claim 1, wherein the conductive portion is selected from a material group comprising Ti, W, Ta, Co, Mo, Ni, Pt, TiAl, TiW, and single or multiple combinations thereof.

3. The phase change memory device as claimed in claim 1, wherein the nitrogen-containing metal silicide part comprises metal silicide with metal elements selected from the material group comprising Ti, W, Ta, Co, Mo, Ni, Pt, TiAl, TiW, and single or multiple combinations thereof.

4. The phase change memory device as claimed in claim 1, wherein the area of the conductive portion exceeds that of the nitrogen-containing metal silicide part.

5. The phase change memory device as claimed in claim 1, wherein the cross section of the nitrogen-containing metal silicide part is a solid circle, a solid oval, a solid square, a solid rectangle, or a solid rhombus.

6. The phase change memory device as claimed in claim 1, wherein the cross section of the nitrogen-containing metal silicide part is a hollow circle, a hollow oval, a hollow square, a hollow rectangle, or a hollow rhombus.

7. The phase change memory device as claimed in claim 1, further comprising a semiconductor substrate and a first dielectric layer disposed on the semiconductor substrate, wherein the first dielectric layer comprises a through hole therein.

8. The phase change memory device as claimed in claim 7 wherein the heating element is disposed in the through hole, and wherein the relatively high resistive portion is formed at the upper portion of the through hole and is level with the first dielectric layer.

9. The phase change memory device as claimed in claim 7, wherein the heating element is disposed in the through hole, and wherein the relatively high resistive portion is formed overlying the first dielectric layer.

10. The phase change memory device as claimed in claim 9, further comprising a second dielectric layer conformably formed on the first dielectric layer and the relatively high resistive portion, and wherein the second dielectric layer comprises an opening corresponding to the nitrogen-containing metal silicide part.

11. A method for fabricating a phase change memory device, comprising:
providing a semiconductor substrate with a first dielectric layer disposed on the semiconductor layer, wherein the first dielectric layer comprises a through hole therein;
forming a heating element in the through hole, wherein the heating element comprises a conductive portion and a relatively high resistive portion; and
forming a phase change memory layer on the first dielectric layer stacked with the heating element;
wherein the relatively high resistive portion comprises a nitrogen-containing metal silicide part.

12. The method as claimed in claim 11, wherein formation of the heating element in the through hole comprises:
filling a first metal layer in the through hole, wherein in the first metal is level with the first dielectric layer;
forming a silicon layer on the first dielectric layer such that a portion of the silicon layer directly contacts the first metal layer;
performing a heat treatment to form a metal silicide layer on an interface between the silicon layer and the first metal layer; and
nitrifying the metal silicide layer to be transformed into the nitrogen-containing metal silicide part.

13. The method as claimed in claim 12, wherein before nitrifying the metal silicide layer, further comprising removing an un-reacted silicon layer.

14. The method device as claimed in claim 12, wherein before forming the silicon layer on the first dielectric layer, further comprising a patterned isolation layer to confine a contact area between the silicon layer and the first metal layer within a specific region.

15. The method as claimed in claim 14, wherein the specific region is a solid circle, a solid oval, a solid square, a solid rectangle, or a solid rhombus.

16. The method as claimed in claim 14, wherein the specific region is a hollow circle, a hollow oval, a hollow square, a hollow rectangle, or a hollow rhombus.

17. The method as claimed in claim 12, wherein the first metal layer is selected from the material group comprising Ti, W, Ta, Co, Mo, Ni, Pt, TiAl, TiW, and single or multiple combinations thereof.

18. The method as claimed in claim 12, wherein the silicon layer comprises a polysilicon layer or an amorphous silicon layer.

19. The method as claimed in claim 12, wherein the step of nitrifying the metal silicide layer comprises a nitrogen ion implantation or a nitrogen containing plasma treatment.

20. The method as claimed in claim 12, wherein the nitrogen-containing metal silicide part comprises metal silicide with metal elements selected from the material group comprising Ti, W, Ta, Co, Mo, Ni, Pt, TiAl, TiW, and single or multiple combinations thereof.

21. The method as claimed in claim 11, further comprising:
forming a second metal layer on the first dielectric layer and electrically connect the first metal layer;
forming a second dielectric layer on the first dielectric layer, wherein the second dielectric layer is patterned to form an opening exposing the second metal layer at a specific region;
forming a silicon layer on the second dielectric layer such that the silicon layer directly contacts the second metal layer at the specific region;
performing a heat treatment to form a metal silicide layer on an interface between the silicon layer and the first metal layer; and
nitrifying the metal silicide layer to be transformed into the nitrogen-containing metal silicide part.

22. The method as claimed in claim 21, wherein before nitrifying the metal silicide layer, further comprising removing an un-reacted silicon layer.

23. The method as claimed in claim 21, wherein the specific region is a solid circle, a solid oval, a solid square, a solid rectangle, or a solid rhombus.

24. The method as claimed in claim 21, wherein the specific region is a hollow circle, a hollow oval, a hollow square, a hollow rectangle, or a hollow rhombus.

25. The method as claimed in claim 21, wherein the first metal layer is selected from the material group comprising Ti, W, Ta, Co, Mo, Ni, Pt, TiAl, TiW, and single or multiple combinations thereof.

26. The method as claimed in claim 21, wherein the silicon layer comprises a polysilicon layer or an amorphous silicon layer.

27. The method as claimed in claim 21, wherein the step of nitrifying the metal silicide layer comprises a nitrogen ion implantation or a nitrogen containing plasma treatment.

28. The method as claimed in claim 21, wherein the nitrogen-containing metal silicide part comprises metal silicide with metal elements selected from the material group comprising Ti, W, Ta, Co, Mo, Ni, Pt, TiAl, TiW, and single or multiple combinations thereof.
